(19) United States
(12) Patent Application Publication
(10) Pub. No.: US 2024/0088271 A1
(43) Pub. Date: Mar. 14, 2024

(54) SEMICONDUCTOR DEVICE

(71) Applicant: Murata Manufacturing Co., Ltd., Kyoto-fu (JP)

(72) Inventors: Atsushi KUROKAWA, Nagaokakyo-shi (JP); Mari SAJI, Nagaokakyo-shi (JP)

(73) Assignee: Murata Manufacturing Co., Ltd., Kyoto-fu (JP)

(21) Appl. No.: 18/491,353

(22) Filed: Oct. 20, 2023

Related U.S. Application Data
(63) Continuation of application No. PCT/JP2022/018170, filed on Apr. 19, 2022.

(30) Foreign Application Priority Data
Apr. 23, 2021 (JP) 2021-073400

(51) Int. Cl. H01L 29/73; H01L 23/00; H01L 29/08; H01L 29/417; H01L 29/737

(52) U.S. Cl. CPC H01L 29/7317; H01L 24/16; H01L 29/0817; H01L 29/0821; H01L 29/41708; H01L 29/737; H01L 2224/1601; H01L 2224/16155; H01L 2924/014; H01L 2924/384

(57) ABSTRACT

A semiconductor device has a semiconductor substrate, at least one first transistor that has a mesa structure including one or more semiconductor layers, a first bump that overlaps the first transistor and extends in a first direction, and a second bump, in which the mesa structure has a first end portion on one end side in a second direction and a second end portion on the other end side in the second direction. The opening has a first opening end portion and a second opening end portion that are adjacent in the second direction. In plan view, the first opening end portion is closer to the second bump than the second opening end portion and the first end portion and the second end portion of the mesa structure are disposed between the first opening end portion and the second opening end portion.

### CROSS-REFERENCE TO RELATED APPLICATIONS

This application claims benefit of priority to International Patent Application No. PCT/JP2022/018170, filed Apr. 19, 2022, and to Japanese Patent Application No. 2021-073400, filed Apr. 23, 2021, the entire contents of each are incorporated herein by reference.

### BACKGROUND

### Technical Field

The present disclosure relates to a semiconductor device.

### Background Art

International Publication No. 2015/104967 describes a semiconductor device including a heterojunction bipolar transistor. The semiconductor device described in International Publication No. 2015/104967 is configured such that a bump is provided on a mesa structure (e.g., a structure in which a collector layer, a base layer, and an emitter layer are laminated) of the transistor.

### SUMMARY

In a case where a bump is provided so as to overlap an entire region of a mesa structure of a transistor, heat radiation performance improves (i.e., thermal resistance becomes small), but reliability of a semiconductor device may undesirably decrease, for example, characteristics of the transistor decreases due to stress from the bump.

Accordingly, the present disclosure provides a semiconductor device that can reduce stress occurring in a mesa structure of a transistor.

A semiconductor device according to one aspect of the present disclosure includes a semiconductor substrate; at least one first transistor that is provided on the semiconductor substrate and has a mesa structure including one or more semiconductor layers; a wire layer that covers the mesa structure; and an insulating film that is provided so as to cover the wire layer and has an opening in a region that overlaps at least the mesa structure. The semiconductor device also includes a first bump that overlaps the at least one first transistor, is electrically connected to the wire layer through the opening, and extends in a first direction parallel with the semiconductor substrate; and a second bump that is disposed in a second direction orthogonal to the first direction and extends in the first direction. The mesa structure has a first end portion on one end side in the second direction and a second end portion on an other end side in the second direction, and the first end portion is disposed closer to the second bump than the second end portion in the second direction. The opening has a first opening end portion and a second opening end portion that are adjacent in the second direction. In plan view in a direction perpendicular to the semiconductor substrate, the first opening end portion is disposed closer to the second bump than the second opening end portion and the first end portion and the second end portion of the mesa structure are disposed between the first opening end portion and the second opening end portion, and a first distance in the second direction between the first opening end portion and the first end portion of the mesa structure is larger than a second distance in the second direction between the second opening end portion and the second end portion of the mesa structure in plan view in the direction perpendicular to the semiconductor substrate.

A semiconductor device according to one aspect of the present disclosure includes a semiconductor substrate; at least one transistor that is provided on the semiconductor substrate and has a mesa structure including one or more semiconductor layers; a wire layer that covers the mesa structure; an insulating film that is provided so as to cover the wire layer and has an opening in a region that overlaps at least the mesa structure, a first bump that overlaps the at least one transistor, is electrically connected to the wire layer through the opening, and extends in a first direction parallel to the semiconductor substrate; and a second bump that is disposed at a position opposite to the first bump across a centroid of the semiconductor substrate. The mesa structure has a first end portion on one end side in a second direction orthogonal to the first direction and a second end portion on an other end side in the second direction, and the first end portion is disposed closer to the centroid of the semiconductor substrate than the second end portion in the second direction. In plan view in a direction perpendicular to the semiconductor substrate, an outer circumference of the first bump has a first side and a second side that extend in the first direction and are adjacent in the second direction and the first side is disposed closer to the centroid of the semiconductor substrate than the second side in the second direction. The opening has a first opening end portion and a second opening end portion that are adjacent in the second direction, and in plan view in the direction perpendicular to the semiconductor substrate, the first opening end portion is disposed between the first end portion of the mesa structure and the first side and the second opening end portion is disposed between the second end portion of the mesa structure and the second side. A first distance in the second direction between the first opening end portion and the first end portion of the mesa structure is larger than a second distance in the second direction between the second opening end portion and the second end portion of the mesa structure in plan view in the direction perpendicular to the semiconductor substrate.

According to the semiconductor device according to the present disclosure, stress occurring in the mesa structure of the transistor can be reduced.

### BRIEF DESCRIPTION OF THE DRAWINGS

FIG. 1 is a plan view of a semiconductor device according to a first embodiment;

FIG. 2 is a cross-sectional view taken along line II-Ir of FIG. 1;

FIG. 3 is a graph schematically illustrating a relationship between a position of a transistor in a second direction and stress;

FIG. 4 is a plan view of a semiconductor device according to a second embodiment;

FIG. 5 is a cross-sectional view of a semiconductor device according to a third embodiment;

FIG. 6 is a cross-sectional view illustrating a cross-sectional shape of a mesa structure of a transistor according to a first modification;

FIG. 7 is a cross-sectional view illustrating a cross-sectional shape of a mesa structure of a transistor according to a second modification;

FIG. 8 is a plan view illustrating a configuration of a plurality of transistors and a bump that overlaps the plurality of transistors according to a third modification; and

FIG. 9 is a plan view illustrating a plurality of transistors and a bump that overlaps the plurality of transistors according to a fourth modification.

### DETAILED DESCRIPTION

Embodiments of a semiconductor device according to the present disclosure are described in detail below with reference to the drawings. Note that the present disclosure is not limited by the embodiments. Needless to say, the embodiments are illustrative, and partial substitution or combination of configurations illustrated in different embodiments is possible. In second and subsequent embodiments, description of matters identical to those in a first embodiment is omitted, and only differences are described. In particular, similar effects produced by similar configurations are not mentioned repeatedly in each embodiment.

### First Embodiment

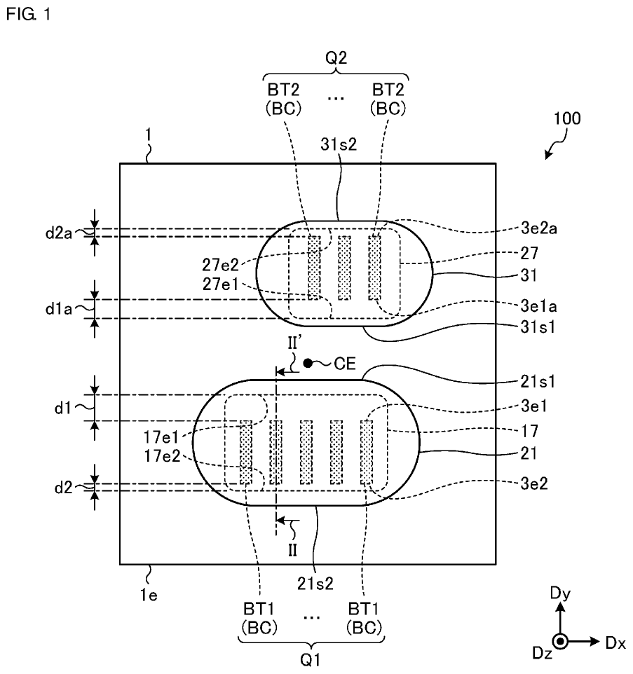

FIG. 1 is a plan view of a semiconductor device according to the first embodiment. Note that FIG. 1 schematically illustrates a positional relationship of mesa structures BC each including a collector layer 3 and a base layer 4 of each of transistors (a first transistor BT1 and a second transistor BT2) while omitting a detailed configuration of each transistor.

As illustrated in FIG. 1, a semiconductor device 100 includes a semiconductor substrate 1, a first transistor group Q1, a second transistor group Q2, a first bump 21, and a second bump 31.

In the following description, one direction within a plane parallel to a surface of the semiconductor substrate 1 is referred to as a first direction Dx. Furthermore, a direction orthogonal to the first direction Dx within the plane parallel to the surface of the semiconductor substrate 1 is referred to as a second direction Dy. Furthermore, a direction orthogonal to the first direction Dx and the second direction Dy is referred to as a third direction Dz. The third direction Dz is a direction perpendicular to the surface of the semiconductor substrate 1. In the present specification, plan view is a positional relationship viewed in the third direction Dz.

The first transistor group Q1 and the second transistor group Q2 are provided on the surface of the semiconductor substrate 1. The first transistor group Q1 and the second transistor group Q2 are disposed adjacent to each other so as to be spaced apart from each other in the second direction Dy. The first transistor group Q1 has a plurality of first transistors BT1. The second transistor group Q2 has a plurality of second transistors BT2. The first transistors BT1 and the second transistors BT2 are heterojunction bipolar transistors (HBTs).

The first transistors BT1 and the second transistors BT2 are also called unit transistors. A unit transistor is defined as a minimum transistor that constitutes the first transistor group Q1 or the second transistor group Q2. The first transistors BT1 are electrically connected in parallel and constitute the first transistor group Q1. The second transistors BT2 are electrically connected in parallel and constitute the second transistor group Q2.

The plurality of first transistors BT1 of the first transistor group Q1 are aligned in the first direction Dx. Each of the plurality of first transistors BT1 extends in the second direction Dy. Similarly, the plurality of second transistors BT2 of the second transistor group Q2 are aligned in the first direction Dx. Each of the plurality of second transistors BT2 extends in the second direction Dy.

In the example illustrated in FIG. 1, the first transistor group Q1 is constituted by five first transistors BT1, and the second transistor group Q2 is constituted by three second transistors BT2. However, the number and layout of the first transistors BT1 and the second transistors BT2 are an example, and can be changed as appropriate.

A centroid CE of the semiconductor substrate 1 is located between the first transistor group Q1 and the second transistor group Q2 that are adjacent in the second direction Dy. The semiconductor substrate 1 has a quadrangular shape (rectangular shape) in plan view, and the centroid CE coincides with an intersection of diagonal lines of the semiconductor substrate 1.

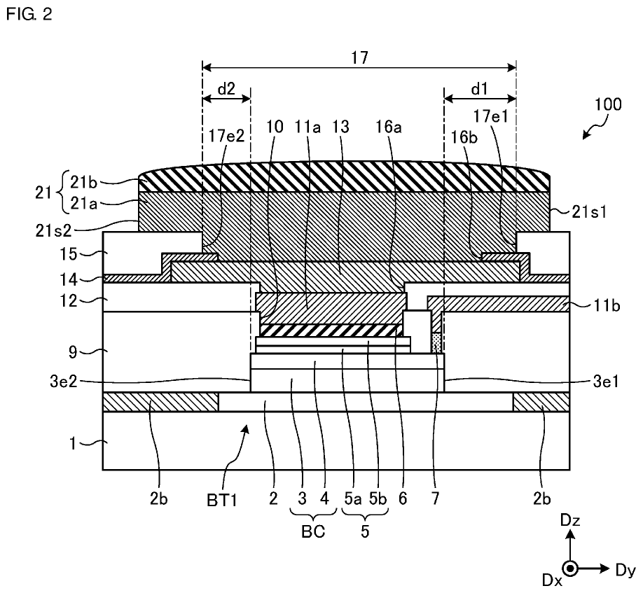

The first bump 21 overlaps the plurality of first transistors BT1 of the first transistor group Q1. The first bump 21 is electrically connected to the plurality of first transistors BT1 through an opening 17 of an organic insulating film 15 (see FIG. 2). The first bump 21 has an oval shape in plan view, extends in the first direction Dx, and is provided along a direction in which the plurality of first transistors BT1 are aligned.

In plan view, an outer circumference of the first bump 21 has a first side 21s1 and a second side 21s2 that extend in the first direction Dx and are adjacent in the second direction Dy. The first side 21s1 of the first bump 21 is disposed closer to the centroid CE of the semiconductor substrate 1 than the second side 21s2 in the second direction Dy.

The first bump 21 is provided so as to cover entire regions of the plurality of first transistors BT1. Specifically, each of the mesa structures BC of the plurality of first transistors BT1 has a first end portion 3e1 on one end side in the second direction Dy and a second end portion 3e2 on the other end side in the second direction Dy. The first end portion 3e1 is disposed closer to the second bump 31 than the second end portion 3e2 in the second direction Dy. In other words, the first end portion 3e1 of each of the mesa structures BC of the first transistors BT1 is disposed closer to the centroid CE of the semiconductor substrate 1 than the second end portion 3e2. The first end portion 3e1 and the second end portion 3e2 of each of the mesa structures BC of the first transistors BT1 are disposed between the first side 21s1 and the second side 21s2 of the first bump 21.

The opening 17 has a first opening end portion 17e1 and a second opening end portion 17e2 that are adjacent in the second direction Dy. In plan view, the first opening end portion 17e1 is disposed closer to the second bump 31 than the second opening end portion 17e2. In plan view, the first opening end portion 17e1 is disposed between the first end portion 3e1 of the mesa structure BC and the second bump 31. The first end portion 3e1 and the second end portion 3e2 of each of the mesa structures BC are disposed between the first opening end portion 17e1 and the second opening end portion 17e2.

Similarly, the second bump 31 overlaps the plurality of second transistors BT2 of the second transistor group Q2. The second bump 31 is electrically connected to the plurality of second transistors BT2 through an opening 27 of an insulating film (not illustrated). The second bump 31 extends in the first direction Dx and is provided along a direction in which the plurality of second transistors BT2 are aligned.

In plan view, an outer circumference of the second bump 31 has a first side 31s1 and a second side 31s2 that extend in the first direction Dx and are adjacent in the second direction Dy. The first side 31s1 of the second bump 31 is disposed closer to the centroid CE of the semiconductor substrate 1 than the second side 31s2 in the second direction Dy. That is, the second bump 31 extends in a direction parallel with the first bump 21 and is disposed adjacent to the first bump 21 in the second direction Dy. The first side 21s1 of the first bump 21 faces the first side 31s1 of the second bump 31 in the second direction Dy.

The second bump 31 is provided so as to cover entire regions of the plurality of second transistors BT2. Specifically, each of the mesa structures BC of the plurality of second transistors BT2 has a first end portion 3e1a on one end side in the second direction Dy and a second end portion 3e2a on the other end side in the second direction Dy. The first end portion 3e1a is disposed closer to the first bump 21 than the second end portion 3e2a in the second direction Dy. In other words, the first end portion 3e1a of each of the mesa structures BC of the second transistors BT2 is disposed closer to the centroid CE of the semiconductor substrate 1 than the second end portion 3e2a. The first end portion 3e1a and the second end portion 3e2a of each of the mesa structures BC of the second transistors BT2 are disposed between the first side 31s1 and the second side 31s2 of the second bump 31.

The opening 27 has a first opening end portion 27e1 and a second opening end portion 27e2 that are adjacent in the second direction Dy. In plan view, the first opening end portion 27e1 is disposed closer to the first bump 21 than the second opening end portion 27e2. In plan view, the first opening end portion 27e1 is disposed between the first end portion 3e1a of each of the mesa structures BC and the first bump 21. The first end portion 3e 1a and the second end portion 3e2a of each of the mesa structures BC are disposed between the first opening end portion 27e1 and the second opening end portion 27e2.

In the configuration in which the first bump 21 that overlaps at least one first transistor BT1 extends in the first direction Dx and a long side (the first side 21s1) of the outer circumference of the first bump 21 is adjacent to a long side (the first side 31s1) of the outer circumference of the other second bump 31 as described above, stress caused by the first bump 21 and the second bump 31 increases on a side where the first bump 21 and the second bump 31 face each other (on a side where the centroid CE of the semiconductor substrate 1 is located).

In the present embodiment, the first bump 21 overlaps the plurality of first transistors BT1 of the first transistor group Q1, and a positional relationship between the first transistors BT1 and the opening 17 is deviated. More specifically, in plan view in a direction perpendicular to the semiconductor substrate 1, a first distance d1 in the second direction Dy between the first opening end portion 17e1 and the first end portion 3e1 of each of the mesa structures BC of the first transistors BT1 is larger than a second distance d2 in the second direction Dy between the second opening end portion 17e2 and the second end portion 3e2 of each of the mesa structures BC of the first transistors BT1.

A distance between an end portion 1e closer to the first bump 21 than the second bump 31 among end portions of the semiconductor substrate 1 in the second direction Dy and the first side 21s1 of the first bump 21 is larger than a distance between the end portion 1e of the semiconductor substrate 1 and the second side 21s2 of the first bump 21. In other words, the first distance d1 on a side where the centroid CE of the semiconductor substrate 1 is located is larger than the second distance d2 on a side where the end portion 1e of the semiconductor substrate 1 is provided. Note that in a case where a single first bump 21 is provided so as to overlap the plurality of first transistors BT1, the first distance d1 and the second distance d2 are averages of the plurality of first transistors BT1.

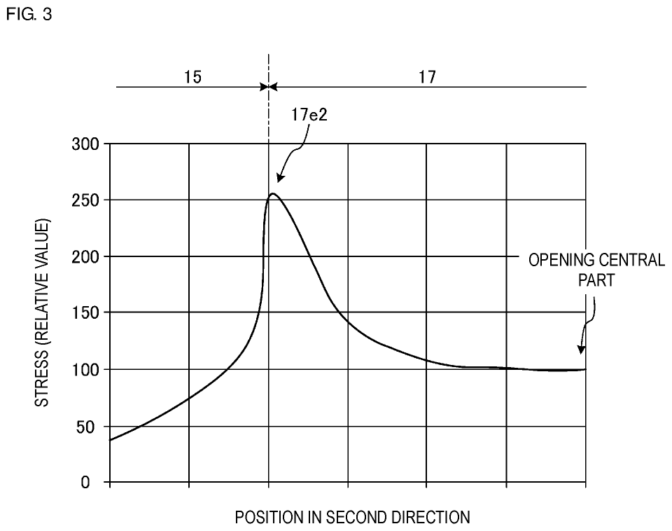

With this configuration, the first end portion 3e1 of each of the mesa structures BC of the first transistors BT1 is disposed away from the first opening end portion 17e1 of the opening 17 (the first side 21s1 of the first bump 21 that is adjacent to the second bump 31) where relatively large stress is generated. This can reduce stress generated in the mesa structures BC of the first transistors BT1 due to the first bump 21. Note that the stress reducing effect of the present embodiment will be described later with reference to FIG. 3.

Similarly, the second bump 31 overlaps the plurality of second transistors BT2 of the second transistor group Q2, and a positional relationship between the second transistor BT2 and the opening 27 is deviated. More specifically, in plan view in a direction perpendicular to the semiconductor substrate 1, a first distance d1a in the second direction Dy between the first opening end portion 27e1 and the first end portion 3e1a of each of the mesa structures BC of the second transistors BT2 is larger than a second distance d2a in the second direction Dy between the second opening end portion 27e2 and the second end portion 3e2a of each of the mesa structures BC of the second transistors BT2.

Next, a detailed cross-sectional configuration of the semiconductor device 100 is described. FIG. 2 is a cross-sectional view taken along line II-II′ of FIG. 1. Note that although the first transistor BT1 of the first transistor group Q1 and the first bump 21 are illustrated in FIG. 2, description of a laminated structure in which the first transistor BT1 of the first transistor group Q1 and the first bump 21 are laminated is applicable to a laminated structure in which the second transistor BT2 of the second transistor group Q2 and the second bump 31 are laminated.

As illustrated in FIG. 2, in the semiconductor device 100, the first transistor BT1 includes a sub collector layer 2, a collector layer 3, a base layer 4, an emitter layer 5, an emitter electrode 6, a base electrode 7, and a collector electrode (not illustrated). In the first transistor BT1, the sub collector layer 2, the collector layer 3, the base layer 4, and the emitter layer 5 are laminated on the semiconductor substrate 1 in this order.

The mesa structure BC of the present embodiment includes the collector layer 3 and the base layer 4. The first end portion 3e1 and the second end portion 3e2 of the mesa structure BC are defined by positions of end portions of the collector layer 3 in the second direction Dy and a position of a lower end portion of the collector layer 3 that makes contact with the sub collector layer 2. The emitter layer 5 includes an intrinsic emitter layer 5a and an emitter mesa layer 5b. That is, the emitter layer 5 also forms an emitter mesa structure.

The emitter electrode 6, a first wire 11a, and a second wire 13 (emitter wire) are laminated in this order on the emitter layer 5. An inorganic insulating film 14 and the organic insulating film 15 (insulating film) cover the second wire 13 and have openings 16b and 17 in regions that overlap at least the collector layer 3, respectively. The first bump 21 is provided on the organic insulating film 15 and is electrically connected to the second wire 13 through the openings 16b and 17.

More specifically, the semiconductor substrate 1 is, for example, a semi-insulating GaAs (gallium arsenide) substrate). The sub collector layer 2 is provided on the semiconductor substrate 1. The sub collector layer 2 is a high-concentration n-type GaAs layer and has, for example, a thickness of approximately 0.5 μm. The collector layer 3 is provided on the sub collector layer 2. The collector layer 3 is an n-type GaAs layer and has, for example, a thickness of approximately 1 μm. The base layer 4 is provided on the collector layer 3. The base layer 4 is a p-type GaAs layer and has, for example, a thickness of approximately 100 nm.

The emitter layer 5 is provided on the base layer 4. The emitter layer 5 includes the intrinsic emitter layer 5a on a base layer 4 side and the emitter mesa layer 5b provided on the intrinsic emitter layer 5a. The intrinsic emitter layer 5a is an n-type InGaP (indium gallium phosphide) layer and has, for example, a thickness of 30 nm or more and 40 nm or less (i.e., from 30 nm to 40 nm). The emitter mesa layer 5b is formed by a high-concentration n-type GaAs layer and a high-concentration n-type InGaAs layer. The high-concentration n-type GaAs layer and the high-concentration n-type InGaAs layer each have, for example, a thickness of approximately 100 nm. The high-concentration n-type InGaAs layer of the emitter mesa layer 5b is provided for ohmic contact with the emitter electrode 6.

The base layer 4 and the collector layer 3 are epitaxial grown on the semiconductor substrate 1 and are then subjected to etching treatment to form the mesa structure BC. Note that the mesa structure BC may be formed by the base layer 4 and an upper part of the collector layer 3 without removing a lower part of the collector layer 3.

The collector electrode (not illustrated) is provided on the sub collector layer 2 in contact with the sub collector layer 2. The collector electrode is, for example, disposed adjacent to the mesa structure BC (the base layer 4 and the collector layer 3) in the first direction Dx. The collector electrode has, for example, a laminated film in which a gold germanium (AuGe) film, a nickel (Ni) film, and a gold (Au) film are laminated in this order. The AuGe film has, for example, a film thickness of 60 nm. The Ni film has, for example, a film thickness of 10 nm. The Au film has, for example, a film thickness of 200 nm.

The base electrode 7 is provided on the base layer 4 in contact with the base layer 4. The base electrode 7 is a laminated film in which a Ti film, a Pt film, and an Au film are laminated in this order. The Ti film has, for example, a film thickness of 50 nm. The Pt film has, for example, a film thickness of 50 nm. The Au film has, for example, a film thickness of 200 nm.

The emitter electrode 6 is provided on the emitter mesa layer 5b of the emitter layer 5 in contact with the emitter mesa layer 5b. The emitter electrode 6 is a titanium (Ti) film). The Ti film has, for example, a film thickness of 50 nm.

Note that an isolation region 2b is provided adjacent to the sub collector layer 2 on the semiconductor substrate 1. The isolation region 2b is made insulating by an ion implantation technique. Elements (the plurality of first transistors BT1) are insulated from each other by the isolation region 2b.

A first insulating film 9 covers the emitter electrode 6, the base electrode 7, and the collector electrode (not illustrated), and is provided on the sub collector layer 2 and the isolation region 2b. The first insulating film 9 is, for example, a silicon nitride (SiN) layer. The first insulating film 9 may be a single layer or may be a plurality of nitride layers or oxide layers that are laminated. The first insulating film 9 may have a laminated structure in which a SiN layer and a resin layer are laminated.

The first wires 11a and 11b are provided on the first insulating film 9. The first insulating film 9 has a first insulating film opening 10, and the first wire 11a is connected to the emitter electrode 6 through the first insulating film opening 10. Similarly, the first wire 11b is connected to the base electrode 7 through an opening of the first insulating film 9. Note that a first wire 11c connected to the collector electrode is also provided on the first insulating film 9 although this is not illustrated in FIG. 2.

The first wires 11a and 11b are, for example, Au films. The Au film has, for example, a film thickness of approximately 1 μm. A second insulating film 12 is provided on the first insulating film 9 so as to cover the plurality of first wires 11a and 11b. The second insulating film 12 is made of a similar material to the first insulating film 9. The second insulating film 12 may be, for example, a single-layer film constituted by a SiN layer or may have a laminated structure in which a SiN layer and a resin layer are laminated. The second insulating film 12 has a second insulating film opening 16a in a portion that overlaps the first wire 11a.

The second wire 13 is provided on the second insulating film 12 and is connected to the first wire 11a through the second insulating film opening 16a. The second wire 13 is electrically connected to the emitter layer 5 by the first wire 11a. The second wire 13 is mainly made of a metal material such as Au or Cu. The second wire 13 is formed so as to cover the whole first transistor BT1 including the collector layer 3, the base layer 4, and the emitter layer 5.

The inorganic insulating film 14 is provided so as to cover the second wire 13, and the organic insulating film 15 is provided on the inorganic insulating film 14. The inorganic insulating film 14 is, for example, an inorganic protection film made of an inorganic material including at least one of SiN and silicon oxynitride (SiON). Note that the inorganic insulating film 14 can be omitted as needed.

The organic insulating film 15 is, for example, an organic protection film made of an organic material such as polyimide or BCB. The inorganic insulating film 14 and the organic insulating film 15 (insulating film) have the openings 16b and 17 in regions that overlap the second wire 13, respectively.

The first bump 21 is formed so as to cover the openings 16b and 17 and is formed so as to be in contact with the organic insulating film 15 located along an opening end of the opening 17. As illustrated in FIG. 2, the first bump 21 is a pillar bump and has a laminated structure in which a metal post 21a and solder 21b are laminated. The metal post 21a is, for example, Cu and has a film thickness of approximately 10 μm or more and 50 μm or less (i.e., from 10 μm to 50 μm). The solder 21b is, for example, Sn or an alloy of Sn and Ag and has a film thickness of approximately 10 μm or more and 30 μm or less (i.e., from 10 μm to 30 μm). Note that a metal layer (under bump metal (UBM)) may be provided below the first bump 21.

Positions of the first side 21s1 and the second side 21s2 of the first bump 21 in the second direction Dy are positions of lower end portions of side surfaces of the first bump 21, more specifically, positions where the side surfaces of the first bump 21 are in contact with the organic insulating film 15.

The first opening end portion 17e1 and the second opening end portion 17e2 of the opening 17 are defined by inner walls of the organic insulating film 15 that face each other in the second direction Dy. The first distance d1 in the second direction Dy between the first opening end portion 17e1 and the first end portion 3e1 of the mesa structure BC of the first transistor BT1 and the second distance d2 in the second direction Dy between the second opening end portion 17e2 and the second end portion 3e2 of the mesa structure BC of the first transistor BT1 can be rephrased as a distance in the second direction Dy between an inner wall of the organic insulating film 15 and an end portion of the collector layer 3 of the mesa structure BC.

FIG. 3 is a graph schematically illustrating a relationship between a position of a transistor in a second direction and stress. The graph illustrated in FIG. 3 illustrates a simulation result of a thermal stress distribution in a case where solder mounting was performed at 260° C. and the temperature was changed back to a room temperature. The horizontal axis of the graph illustrated in FIG. 3 represents a position in the second direction Dy, and the vertical axis represents stress applied to an upper surface of the second wire 13. The stress is illustrated as a relative value assuming that stress at a central part of the opening 17 is 100.

As illustrated in FIG. 3, stress is concentrated and rapidly rises at the second opening end portion 17e2 of the opening 17. Furthermore, the stress exhibits a lower value in a central region of the opening than at the second opening end portion 17e2. The stress exhibits a still lower value in a region where the organic insulating film 15 is provided outside the opening 17 than in the central part of the opening. FIG. 3 indicates that thermal stress is reduced in a region that overlaps the organic insulating film 15 since a Young's modulus of the organic insulating film 15 is smaller than metal materials that constitute the second wire 13 and the first bump 21 and a semiconductor material of the first transistor B T1.

Note that although the opening 17 is provided in the organic insulating film 15, the opening 17 may be provided in the inorganic insulating film 14 or an inorganic insulating film may be laminated instead of the organic insulating film 15. Even in this case, the effect of mitigating the thermal stress of the first bump 21 can be obtained.

As a comparative example, regarding a semiconductor device formed so that the first distance d1 and the second distance d2 were equal, a distribution of thermal stress obtained in a case where solder mounting was performed at 260° C. and the temperature was changed back to a room temperature was calculated by simulation. For example, in a case where the first distance d1 and the second distance d2 are d1=d2=22.5 μm, stress generated at the first end portion 3e1 (that is, the first end portion 3e1 closer to the second bump 31) of the mesa structure BC of the first transistor BT1 increases to 121% with respect to stress generated at the second end portion 3e2 (that is, the second end portion 3e2 farther from the second bump 31) of the mesa structure BC.

As Example of the present embodiment, as for the semiconductor device 100 formed so that the first distance d1 was larger than the second distance d2, a distribution of thermal stress obtained in a case where solder mounting was performed at 260° C. and the temperature was changed back to a room temperature was calculated by simulation. For example, in a case where the first distance d1 was 26 μm and the second distance d2 was 19 μm, stress generated at the first end portion 3e1 (that is, the first end portion 3e1 closer to the second bump 31) of the mesa structure BC of the first transistor BT1 decreased by 10% as compared with the comparative example. On the other hand, stress generated at the second end portion 3e2 (that is, the second end portion 3e2 farther from the second bump 31) of the mesa structure BC was similar to that in the comparative example.

As described above, the semiconductor device 100 according to the present embodiment includes the semiconductor substrate 1, at least one first transistor BT1 that is provided on the semiconductor substrate 1 and has the mesa structure BC including a plurality of semiconductor layers (e.g., the collector layer 3 and the base layer 4), a wire layer (the second wire 13) that covers the mesa structure BC, an insulating film (the organic insulating film 15) that is provided so as to cover the wire layer and has the opening 17 in a region that overlaps at least the mesa structure BC, the first bump 21 that overlaps the at least one first transistor BT1, is electrically connected to the wire layer through the opening 17, and extends in the first direction Dx parallel with the semiconductor substrate 1, and the second bump 31 that is disposed adjacent to the first bump 21 in the second direction Dy orthogonal to the first direction Dx and extends in the first direction Dx. The mesa structure BC has the first end portion 3e1 on one end side in the second direction Dy and the second end portion 3e2 on the other end side in the second direction Dy, and the first end portion 3e1 is disposed closer to the second bump 31 than the second end portion 3e2 in the second direction Dy. The opening 17 has the first opening end portion 17e1 and the second opening end portion 17e2 that are adjacent in the second direction Dy, and in plan view in a direction perpendicular to the semiconductor substrate 1, the first opening end portion 17e1 is disposed closer to the second bump 31 than the second opening end portion 17e2 and the first end portion 3e1 and the second end portion 3e2 of the mesa structure BC are disposed between the first opening end portion 17e1 and the second opening end portion 17e2. In plan view in the direction perpendicular to the semiconductor substrate 1, the first distance d1 in the second direction Dy between the first opening end portion 17e1 and the first end portion 3e1 of the mesa structure BC is larger than the second distance d2 in the second direction Dy between the second opening end portion 17e2 and the second end portion 3e2 of the mesa structure BC.

With this configuration, the semiconductor device 100 can improve heat radiation performance since the first bump 21 is provided so as to cover an entire region of the mesa structure BC of the first transistor BT1. Furthermore, the semiconductor device 100 is formed so that the first distance d1 is larger than the second distance d2 in the configuration in which the first bump 21 and the second bump 31 are provided adjacent to each other. With this configuration, the first end portion 3e1 of the mesa structure BC is provided away from the first opening end portion 17e1 of the opening 17 where stress is concentrated, and therefore stress generated in the mesa structure BC of the first transistor BT1 can be reduced.

Note that although the first bump 21 and the mesa structure BC of the first transistor BT1 are described in FIGS. 2 and 3, the same applies to the second bump 31 and the mesa structure BC of the second transistor BT2 (see FIG. 1), that is, the first distance d1a in the second direction Dy between the first opening end portion 27e1 and the first end portion 3e1a of the mesa structure BC of the second transistor BT2 is larger than the second distance d2a in the second direction Dy between the second opening end portion 27e2 and the second end portion 3e2a of the mesa structure BC of the second transistor BT2. With this configuration, stress generated at the first end portion 3e1a of the mesa structure BC of the second transistor BT2 can also be reduced.

Note that although the first distance d1 and the second distance d2 are defined by the mesa structure BC including the collector layer 3 and the base layer 4, the first distance d1 and the second distance d2 may be a distance between the mesa structure of the emitter layer 5 and the first opening end portion 17e1 and a distance between the mesa structure of the emitter layer 5 and the second opening end portion 17e2. However, a mesa structure BC having a larger step is effective for a reduction in stress. Although the whole collector layer 3 is included in the mesa structure BC in the present example, the mesa structure BC may include the base layer 4 and a part of the collector layer 3. In the present example, only the first bump 21 and the second bump 31 are provided on the semiconductor substrate 1. As a modification, a third bump may be present in a region between the first bump 21 and the second bump 31. An effect similar to that described in the present example is produced for mitigation of stress of the first bump 21 or the second bump 31 that is applied to a mesa.

### Second Embodiment

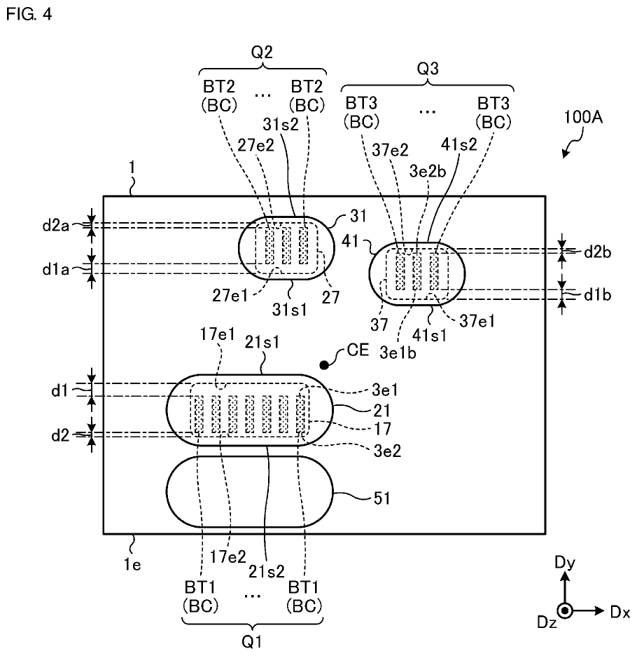

FIG. 4 is a plan view of a semiconductor device according to the second embodiment. In the second embodiment, a configuration in which a third bump 41 and a fourth bump 51 are provided unlike the first embodiment is described. Note that a positional relationship between a first transistor group Q1 (a plurality of first transistors BT1) and a first bump 21 and a second transistor group Q2 (a plurality of second transistors BT2) and a second bump 31 is similar to that in the first embodiment, and repeated description thereof is omitted.

As illustrated in FIG. 4, in a semiconductor device 100A according to the second embodiment, the third bump 41 overlaps a third transistor group Q3 (a plurality of third transistors B T3). A laminated structure in which the third bump 41 and the third transistor BT3 are laminated is similar to that in the first embodiment (see FIG. 2). That is, the third bump 41 is electrically connected to the third transistor BT3 through an opening 37 of an organic insulating film 15 (see FIG. 2). A first end portion 3e1b and a second end portion 3e2b of a mesa structure BC are disposed between a first opening end portion 37e1 and a second opening end portion 37e2 of the opening 37 and between a first side 41s1 and a second side 41s2 of the third bump 41.

The third bump 41 and the third transistor group Q3 are located in an oblique direction that crosses the first direction Dx and the second direction Dy with respect to the first bump 21 and the first transistor group Q1. The third bump 41 and the third transistor group Q3 are disposed at a position opposite to the first bump 21 and the first transistor group Q1 across a centroid CE of the semiconductor substrate 1.

Furthermore, the third bump 41 and the third transistor group Q3 are disposed adjacent to the second bump 31 and the second transistor group Q2 in the first direction Dx. A distance (shortest distance) between the first bump 21 and the third bump 41 is longer than a distance (shortest distance) between the second bump 31 and the third bump 41.

The fourth bump 51 is disposed adjacent to the first bump 21 and the first transistor group Q1 in the second direction Dy. More specifically, the fourth bump 51 is disposed closer to an end portion 1e of the semiconductor substrate 1 (farther from the centroid CE) than the first bump 21 and the first transistor group Q1. The fourth bump 51 is, for example, a terminal that is electrically connected to a collector electrode of the plurality of first transistors BT1 of the first transistor group Q1 and is provided so as not to overlap transistors such as the first transistors BT1. A distance (shortest distance) between the first bump 21 and the second bump 31 is longer than a distance (shortest distance) between the first bump 21 and the fourth bump 51. A distance (shortest distance) between the first bump 21 and the third bump 41 is longer than a distance (shortest distance) between the first bump 21 and the fourth bump 51.

In the configuration in which a plurality of bumps (the first bump 21 to the fourth bump 51) are provided as described above, stress generated in the mesa structure BC is larger in a case where a distance between bumps is larger than in a case where a distance between bumps is smaller.

That is, as for the first bump 21 and the first transistor group Q1 (the plurality of first transistors BT1), stress generated at a second end portion 3e2 of the mesa structure BC on a side where the fourth bump 51 is disposed close is relatively small, and stress generated at a first end portion 3e1 on a side where the second bump 31 is disposed far is relatively large. As in the first embodiment, a first distance d1 on a side where the second bump 31 is provided is larger than a second distance d2 on a side where the fourth bump 51 is provided. In other words, the first distance d1 on a side where the centroid CE of the semiconductor substrate 1 is located is larger than the second distance d2 on a side where the end portion 1e of the semiconductor substrate 1 is provided. This can reduce stress generated in the mesa structure BC of the first transistor BT1.

As for the second bump 31 and the second transistor group Q2 (the plurality of second transistors BT2), stress generated in the mesa structure BC on a side where the third bump 41 is disposed close is relatively small, and stress generated on a side where the first bump 21 is disposed far is relatively large. Therefore, as in the first embodiment, stress generated in the mesa structure BC of the second transistor BT2 can be reduced by making a first distance d1a on a side where the first bump 21 is provided (on a side where the centroid CE of the semiconductor substrate 1 is located) larger than a second distance d2a.

As for the third bump 41 and the third transistor group Q3 (the plurality of third transistors BT3), the third bump 41 is disposed in an oblique direction with respect to the first bump 21 and the first transistor group Q1 (the plurality of first transistors BT1) and is not disposed adjacent to the first bump 21 and the first transistor group Q1 (the plurality of first transistors BT1) in the second direction Dy. Even in this case, since the third bump 41 is disposed far from the first bump 21 across the centroid CE of the semiconductor substrate 1, stress is larger at the first side 41s1 of the third bump 41 disposed close to the centroid CE of the semiconductor substrate 1 than at the second side 41s2 disposed far from the centroid CE of the semiconductor substrate 1.

In the mesa structures BC of the plurality of third transistors BT3, the first end portion 3e1b is disposed closer to the centroid CE of the semiconductor substrate 1 than the second end portion 3e2b in the second direction Dy. The first distance d1b on a side where the centroid CE of the semiconductor substrate 1 is located is larger than the second distance d2b far from the centroid CE of the semiconductor substrate 1. More specifically, in the third bump 41 and the third transistor group Q3 (the plurality of third transistors BT3), the first distance d1b in the second direction Dy between the first opening end portion 37e1 of the opening 37 on a side where the centroid CE of the semiconductor substrate 1 is located and the first end portion 3e1b of the mesa structure BC is larger than the second distance d2b in the second direction Dy between the second opening end portion 37e2 at a position far from the centroid CE of the semiconductor substrate 1 and the second end portion 3e2b of the mesa structure BC. This can reduce stress generated in the mesa structure BC of the third transistor BT3.

Note that although oval bumps extending in the first direction Dx are provided in FIG. 4, this is not restrictive. For example, a plurality of circular bumps may be disposed side by side.

### Third Embodiment

FIG. 5 is a cross-sectional view of a semiconductor device according to the third embodiment. In the third embodiment, a configuration in which a third wire 18 is provided between a second wire 13 and a first bump 21 unlike the first embodiment and the second embodiment is described. The third wire 18 is also called a redistribution layer. Note that a laminated structure from a semiconductor substrate 1 to the second wire 13 is similar to that in the first embodiment (FIG. 2), and repeated description thereof is omitted.

As illustrated in FIG. 5, in a semiconductor device 100B according to the third embodiment, the third wire 18 is provided on an organic insulating film 15 and an inorganic insulating film 14 and is connected to the second wire 13 through openings 16b and 17. The third wire 18 is electrically connected to an emitter layer 5 by the second wire 13 and a first wire 11a. The third wire 18 is, for example, made of a metal material identical to that of the second wire 13.

An organic insulating film 19 is provided so as to cover the third wire 18. The organic insulating film 19 (insulating film) has an opening 20 in a region that overlaps the third wire 18.

The first bump 21 is formed so as to cover the opening 20 and is formed in contact with the organic insulating film 19 located along an opening end of the opening 20. In the present embodiment, a first distance d1 is defined as a distance in the second direction Dy between a first opening end portion 20e1 of the opening 20 and a first end portion 3e1 of a mesa structure BC of a first transistor BT1. Furthermore, a second distance d2 is defined as a distance in the second direction Dy between a second opening end portion 20e2 of the opening 20 and a second end portion 3e2 of the mesa structure BC of the first transistor BT1.

In the present embodiment, the first distance d1 is larger than the second distance d2. This can reduce stress generated in the mesa structure BC of the first transistor BT1 due to the first bump 21. In the present embodiment, the first distance d1 and the second distance d2 are defined as distances between opening ends of the opening 20 and the mesa structure BC of the transistor. As a modification, a first distance d1′ and a second distance d2′ may be defined as distances between opening ends of an opening 17 instead of the opening 20 and the mesa structure BC of the transistor, and stress may be reduced by making the first distance d1′ larger than the second distance d2′. Preferably, stress is reduced more by making both of the distances between the opening 20 and the mesa structure BC and the distances between the opening 17 and the mesa structure BC have the relationship of the present embodiment.

Note that the configuration of the third embodiment is also applicable to the semiconductor devices 100 and 100A illustrated in the first embodiment and the second embodiment.

Although a semiconductor device in which a single bump (e.g., the first bump 21) is provided so as to overlap a plurality of transistors (e.g., the first transistors BT1) has been described as an example in each of the above embodiments, this is not restrictive. A semiconductor device in which a single bump is provided so as to overlap a single transistor may be employed. Furthermore, although a pillar bump is described as an example of a bump, for example, a solder bump or a stud bump may be used instead of a pillar bump.

The materials, thicknesses, dimensions, and the like of the constituents illustrated in each of the above embodiments are illustrative and may be changed as appropriate. The materials and thicknesses of the sub collector layer 2, the collector layer 3, the base layer 4, the emitter layer 5, and the various wires may also be changed as appropriate.

(Modifications)

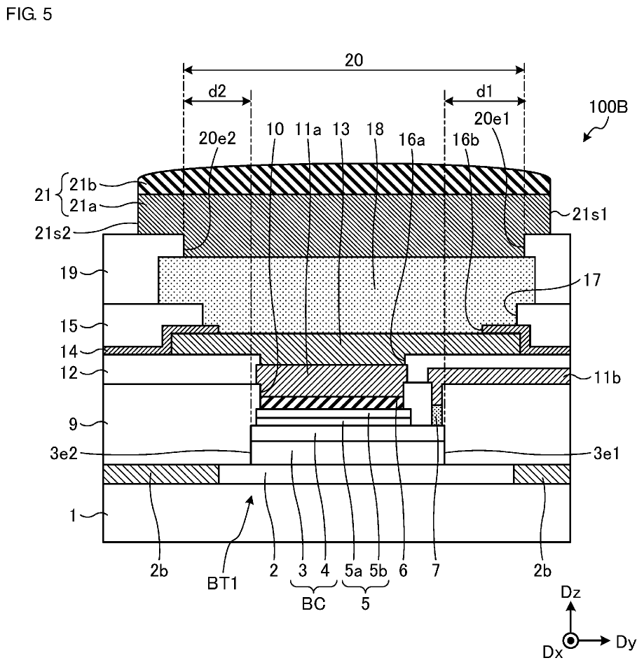

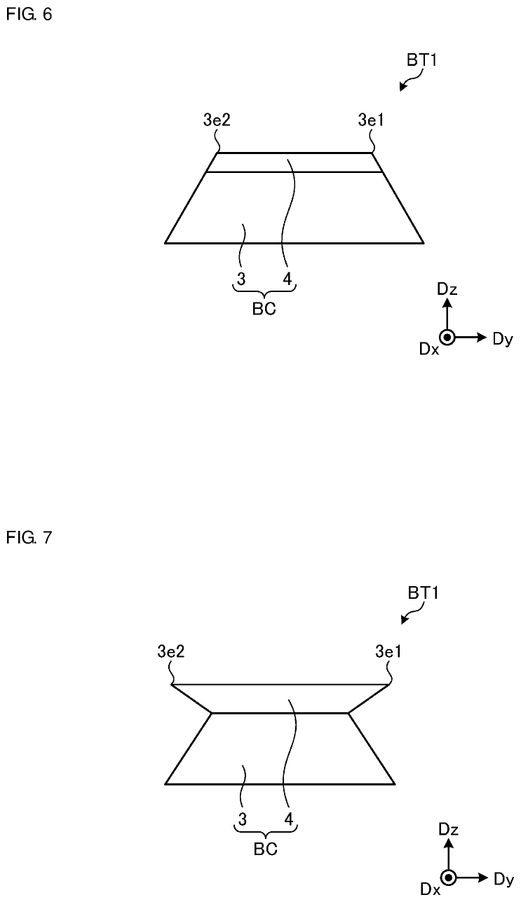

In a case where the cross-sectional shape of the mesa structure BC is not a rectangular shape such as the ones illustrated in the first to third embodiments, a first end portion (e.g., the first end portion 3e1) and a second end portion (the second end portion 3e2) of each of mesa structures BC of a plurality of transistors (e.g., the first transistors BT1) are end portions of a part of the mesa structure BC that is closest to a bump. This is described in detail below with reference to FIGS. 6 and 7.

FIG. 6 is a cross-sectional view illustrating a cross-sectional shape of a mesa structure of a transistor according to a first modification. FIG. 7 is a cross-sectional view illustrating a cross-sectional shape of a mesa structure of a transistor according to a second modification. In the first modification illustrated in FIG. 6, the cross-sectional shape of the mesa structure BC is a trapezoidal shape whose one side (a side of the base layer 4 that is close to the first bump 21) is shorter than the other side (a side of the collector layer 3 that is close to the semiconductor substrate 1) that is opposed to the one side in the third direction Dz. In the second modification illustrated in FIG. 7, the mesa structure BC has such a cross-sectional shape that a trapezoid whose one side is longer than the other side that is opposed to the one side in the third direction Dz and a trapezoid whose one side is shorter than the other side that is opposed to the one side in the third direction Dz are laminated so that shorter sides are in contact with each other. In such cases where the cross-sectional shape of the mesa structure BC is not a rectangular shape such as the one illustrated in FIGS. 2 and 5, the first end portion 3e1 of the mesa structure BC on one end side in the second direction Dy and the second end portion 3e2 on the other end side in the second direction Dy are end portions of a surface, on the first bump 21 side, of the base layer 4 included in the mesa structure BC. Note that although a configuration in which the long side (a side close to the first bump 21) of the base layer 4 and the long side (a side close to the semiconductor substrate 1) of the collector layer 3 have similar lengths is illustrated in FIG. 7, this is not restrictive. The long side of the base layer 4 may be longer than the long side of the collector layer 3 or the long side of the collector layer 3 may be longer than the long side of the base layer 4.

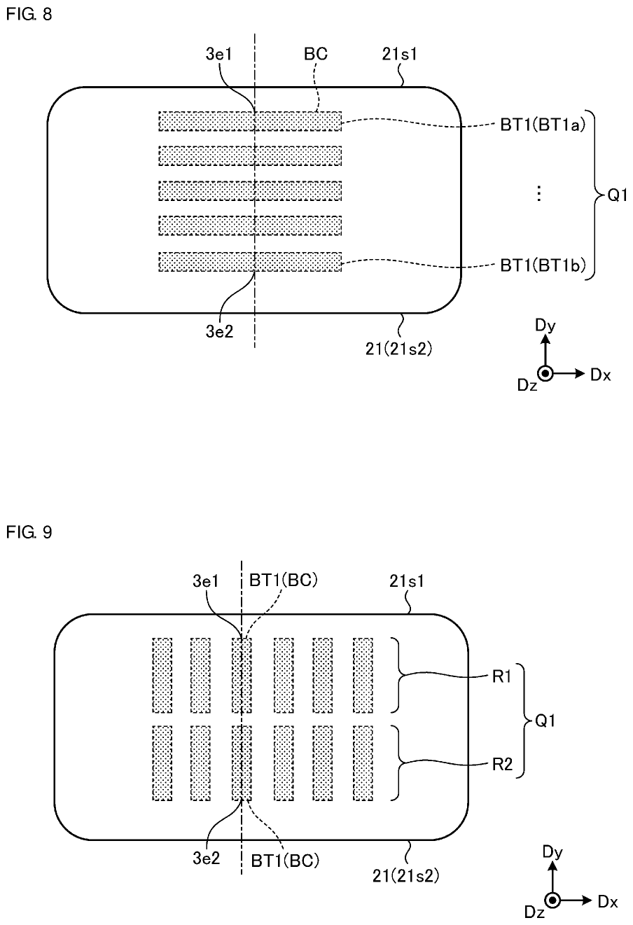

Although a semiconductor device in which a single bump (e.g., the first bump 21) is provided so as to overlap a plurality of transistors (e.g., the first transistors BT1) that have a long side extending along the second direction Dy and are aligned in the first direction Dx has been described as an example in the first to third embodiments, this is not restrictive. This is described below with reference to FIGS. 8 and 9.

FIG. 8 is a plan view illustrating a configuration of a plurality of transistors and a bump that overlaps the plurality of transistors according to a third modification. In the third modification illustrated in FIG. 8, the plurality of transistors (first transistors BT1) have a long side extending along the first direction Dx and are aligned along the second direction Dy. In this case, as illustrated in FIG. 8, the first end portion 3e1 and the second end portion 3e2 of the mesa structure BC are an end portion of a first end transistor BT1a closest to the first side 21s1 of the outer circumference of the first bump 21 in plan view and an end portion of a second end transistor BT1b closest to the second side 21s2 of the outer circumference of the first bump 21 in plan view among the plurality of transistors (the first transistors BT1). Specifically, the first end portion 3e1 of the mesa structure BC is an end portion of the mesa structure BC of the first end transistor BT1a that is closest to the first side 21s1 in the second direction Dy. The second end portion 3e2 of the mesa structure BC is an end portion of the mesa structure BC of the second end transistor BT1b that is closest to the second side 21s2 in the second direction Dy.

FIG. 9 is a plan view illustrating a configuration of a plurality of transistors and a bump that overlaps the plurality of transistors according to a fourth modification. In the fourth modification illustrated in FIG. 9, a plurality of rows R1 and R2 formed by the plurality of transistor (the first transistors BT1) arranged in the first direction Dx are provided, and the bump (the first bump 21) is provided so as to overlap the plural rows of the transistors (the first transistors BT1). In this case, as illustrated in FIG. 9, the first end portion 3e1 and the second end portion 3e2 of the mesa structure BC are an end portion of the first transistor B T1 of the row R1 closest to the first side 21s1 of the outer circumference of the first bump 21 in plan view and an end portion of the first transistor BT1 of the row R2 closest to the second side 21s2 of the outer circumference of the bump 21 in plan view among the plurality of transistors (the first transistors BT1). Specifically, the first end portion 3e1 of the mesa structure BC is an end portion, on the first side 21s1 side, of the first transistor BT1 of the row R1 closest to the first side 21s1 in the second direction Dy. The second end portion 3e2 of the mesa structure BC is an end portion, on the second side 21s2 side, of the first transistor BT1 of the row R2 closest to the second side 21s2 in the second direction Dy.

Note that the above embodiments are for facilitating understanding of the present disclosure, and it should not be interpreted that the present disclosure is limited by the above embodiments. The present disclosure can be changed/modified without departing from the spirit of the present disclosure, and the present disclosure encompasses equivalents thereof

What is claimed is:

1. A semiconductor device comprising:
a semiconductor substrate;
at least one first transistor that is on the semiconductor substrate and has a mesa structure including one or more semiconductor layers;
a wire layer that covers the mesa structure;
an insulating film that covers the wire layer and has an opening in a region that overlaps at least the mesa structure;
a first bump that overlaps the at least one first transistor, is electrically connected to the wire layer through the opening, and extends in a first direction parallel with the semiconductor substrate; and
a second bump that is in a second direction orthogonal to the first direction and extends in the first direction,
wherein
the mesa structure has a first end portion on one end side in the second direction and a second end portion on an other end side in the second direction, and the first end portion is closer to the second bump than the second end portion in the second direction,
the opening has a first opening end portion and a second opening end portion that are adjacent in the second direction, and in plan view in a direction perpendicular to the semiconductor substrate, the first opening end portion is closer to the second bump than the second opening end portion, and the first end portion and the second end portion of the mesa structure are between the first opening end portion and the second opening end portion, and
a first distance in the second direction between the first opening end portion and the first end portion of the mesa structure is larger than a second distance in the second direction between the second opening end portion and the second end portion of the mesa structure in plan view in the direction perpendicular to the semiconductor substrate.

2. The semiconductor device according to claim 1, wherein
in plan view in the direction perpendicular to the semiconductor substrate, an outer circumference of the first bump has a first side and a second side that extend in the first direction and are adjacent in the second direction, and the first side is closer to the second bump than the second side in the second direction, and
a distance between an end portion closer to the first bump than the second bump among end portions of the semiconductor substrate in the second direction and the first side is larger than a distance between the end portion and the second side.

3. A semiconductor device comprising:
a semiconductor substrate;
at least one transistor that is on the semiconductor substrate and has a mesa structure including one or more semiconductor layers;
a wire layer that covers the mesa structure;
an insulating film that covers the wire layer and has an opening in a region that overlaps at least the mesa structure,
a first bump that overlaps the at least one transistor, is electrically connected to the wire layer through the opening, and extends in a first direction parallel to the semiconductor substrate; and
a second bump that is at a position opposite to the first bump across a centroid of the semiconductor substrate,
wherein
the mesa structure has a first end portion on one end side in a second direction orthogonal to the first direction and a second end portion on an other end side in the second direction, and the first end portion is closer to the centroid of the semiconductor substrate than the second end portion in the second direction,
in plan view in a direction perpendicular to the semiconductor substrate, an outer circumference of the first bump has a first side and a second side that extend in the first direction and are adjacent in the second direction and the first side is closer to the centroid of the semiconductor substrate than the second side in the second direction,
the opening has a first opening end portion and a second opening end portion that are adjacent in the second direction, and in plan view in the direction perpendicular to the semiconductor substrate, the first opening end portion is between the first end portion of the mesa structure, and the first side and the second opening end portion is between the second end portion of the mesa structure and the second side, and
a first distance in the second direction between the first opening end portion and the first end portion of the mesa structure is larger than a second distance in the second direction between the second opening end portion and the second end portion of the mesa structure in plan view in the direction perpendicular to the semiconductor substrate.

4. The semiconductor device according to claim 1, further comprising:
a collector layer on the semiconductor substrate;
a base layer on the collector layer; and
an emitter layer on the base layer,
wherein the mesa structure includes at least a part of the collector layer and the base layer.

5. The semiconductor device according to claim 1, wherein
the insulating film is an organic protection film including an organic material.

6. The semiconductor device according to claim 1, further comprising:
at least one second transistor that is on the semiconductor substrate and has a mesa structure including one or more semiconductor layers,
wherein the second bump overlaps the at least one second transistor.

7. The semiconductor device according to claim 2, further comprising:
a collector layer on the semiconductor substrate;
a base layer on the collector layer; and
an emitter layer on the base layer,
wherein the mesa structure includes at least a part of the collector layer and the base layer.

8. The semiconductor device according to claim 3, further comprising:
a collector layer on the semiconductor substrate;
a base layer on the collector layer; and
an emitter layer on the base layer,
wherein the mesa structure includes at least a part of the collector layer and the base layer.

9. The semiconductor device according to claim 2, wherein
the insulating film is an organic protection film including an organic material.

10. The semiconductor device according to claim 3, wherein
the insulating film is an organic protection film including an organic material.

11. The semiconductor device according to claim 4, wherein
the insulating film is an organic protection film including an organic material.

12. The semiconductor device according to claim 7, wherein
the insulating film is an organic protection film including an organic material.

13. The semiconductor device according to claim 8, wherein
the insulating film is an organic protection film including an organic material.

14. The semiconductor device according to claim 2, further comprising:
at least one second transistor that is on the semiconductor substrate and has a mesa structure including one or more semiconductor layers,
wherein the second bump overlaps the at least one second transistor.

15. The semiconductor device according to claim 3, further comprising:
at least one second transistor that is on the semiconductor substrate and has a mesa structure including one or more semiconductor layers,
wherein the second bump overlaps the at least one second transistor.

16. The semiconductor device according to claim 4, further comprising:
at least one second transistor that is on the semiconductor substrate and has a mesa structure including one or more semiconductor layers,
wherein the second bump overlaps the at least one second transistor.

17. The semiconductor device according to claim 5, further comprising:
at least one second transistor that is on the semiconductor substrate and has a mesa structure including one or more semiconductor layers,
wherein the second bump overlaps the at least one second transistor.

18. The semiconductor device according to claim 7, further comprising:
at least one second transistor that is on the semiconductor substrate and has a mesa structure including one or more semiconductor layers,
wherein the second bump overlaps the at least one second transistor.

19. The semiconductor device according to claim 8, further comprising:
at least one second transistor that is on the semiconductor substrate and has a mesa structure including one or more semiconductor layers,
wherein the second bump overlaps the at least one second transistor.

20. The semiconductor device according to claim 9, further comprising:
at least one second transistor that is on the semiconductor substrate and has a mesa structure including one or more semiconductor layers,
wherein the second bump overlaps the at least one second transistor.
